(19) United States
(12) Patent Application Publication
(10) Pub. No.: US 2024/0304660 A1
(43) Pub. Date: Sep. 12, 2024

(54) SEMICONDUCTOR DEVICE, MATCHING CIRCUIT, AND FILTERING CIRCUIT

(71) Applicant: Murata Manufacturing Co., Ltd., Nagaokakyo-shi (JP)

(72) Inventor: Korekiyo ITO, Nagaokakyo-shi (JP)

(21) Appl. No.: 18/666,087

(22) Filed: May 16, 2024

Related U.S. Application Data
(63) Continuation of application No. PCT/JP2022/043131, filed on Nov. 22, 2022.

(30) Foreign Application Priority Data
Dec. 8, 2021 (JP) 2021-199383

(51) Int. Cl. H03H 11/04; H03H 11/28

(52) U.S. Cl. CPC H01L 28/60; H03H 11/04; H03H 11/28

(57) ABSTRACT

A semiconductor device that includes a substrate; a first electrode layer on the substrate; a dielectric film on the first electrode layer, the dielectric film containing silicon oxide, and a ratio of three-membered ring structures to four-membered ring structures in the silicon oxide is 0.46 or less; a second electrode layer on the dielectric film; a protective layer covering the first electrode layer and the second electrode layer, and outer electrodes piercing the protective layer.

### CROSS REFERENCE TO RELATED APPLICATIONS

The present application is a continuation of International application No. PCT/JP2022/043131, filed Nov. 22, 2022, which claims priority to Japanese Patent Application No. 2021-199383, filed Dec. 8, 2021, the entire contents of each of which are incorporated herein by reference.

### TECHNICAL FIELD

The present description relates to a semiconductor device. The present description also relates to a matching circuit and a filtering circuit that use the semiconductor device.

### BACKGROUND ART

A metal-insulator-metal (MIM) capacitor is known as a typical capacitor element used for a semiconductor integrated circuit. The MIM capacitor is a capacitor having a parallel-plate structure in which an insulating film is sandwiched by an upper electrode and a lower electrode.

Patent Document 1 discloses an electronic component that includes a circuit element formed on a substrate, at least one pair of terminal electrodes, and a support member. The terminal electrodes are coupled to the circuit element and disposed so as to oppose each other on at least one surface of the substrate. The support member is formed in a region that does not overlap the circuit element when the at least one surface is viewed in plan, and the support member protrude further outward relative to the at least one pair of the terminal electrodes.

A capacitor 1 is illustrated in FIGS. 1 to 4 of Patent Document 1. The capacitor 1 is an example of the electronic component and includes a rectangular plate-like substrate 2. The capacitor 1 also includes a lower electrode 3 (circuit element), a dielectric layer 4 (circuit element), a first electrode 5a (circuit element), a first electrode 5b (circuit element), a first protective layer 6 (protective layer), a second electrode 7 (circuit element), a second protective layer 8 (protective layer), terminal electrodes 9a and 9b, and support members 10a and 10b, and these elements are laminated on the substrate 2 in this order.

Patent Document 1: Japanese Unexamined Patent Application Publication No. 2012-15333 (Japanese Patent No. 5445357)

### SUMMARY OF THE DESCRIPTION

According to Patent Document 1, the material of the dielectric layer 4 can be a high-dielectric ceramic material, such as PbTiO₃, Pb(Zr,Ti)O₃ (i.e., PZT), PbNb₂O₃, Pb(Mg,Nb)O₃ (i.e., PMN), BaTiO₃, (Ba,Sr)TiO₃ (i.e., BST), CaTiO₃, ZrO₂, HfO₂, TiO₂, Ta₂O₆, Bi₄Ti₄O₁₂, SrBi₂Ta₂O₉, Al₂O₃, Si₃N₄, and SiO₂.

In the case of the semiconductor device described in Patent Document 1, such as the capacitor 1, being used for a capacitor in a matching circuit, etc., the capacitor 1 is required to have a high Q-value, where the Q-value is the inverse of dielectric loss. The dielectric film suitable for increasing Q-value for semiconductor devices, however, has not been studied sufficiently.

The present description is made to address the above problem, and an object of the present description is to provide a semiconductor device having high-Q characteristics. Another object of the present description is to provide a matching circuit and a filtering circuit that use the above semiconductor device.

According to the present description, a semiconductor device includes a substrate; a first electrode layer on the substrate; a dielectric film on the first electrode layer, the dielectric film containing silicon oxide, and a ratio of three-membered ring structures to four-membered ring structures in the silicon oxide is 0.46 or less; a second electrode layer on the dielectric film; a protective layer covering the first electrode layer and the second electrode layer, and outer electrodes piercing the protective layer.

According to the present description, a matching circuit includes the semiconductor device of the present description.

According to the present description, a filtering circuit includes the semiconductor device of the present description.

The present description can provide the semiconductor device having high-Q characteristics. The present description also can provide the matching circuit and the filtering circuit each including the above semiconductor device.

### BRIEF DESCRIPTION OF THE DRAWINGS

FIG. 1 is a cross-sectional view schematically illustrating an example of a capacitor according to a first embodiment of the present description.

FIG. 2 is a plan view schematically illustrating the example of the capacitor according to the first embodiment of the present description.

FIG. 3 is a view schematically illustrating an example structure of silicon oxide.

FIG. 4 is a view illustrating an example of Raman spectrum of the silicon oxide.

FIG. 5 is a graph illustrating a relationship between the Q-value of a 0.2 pF capacitor and the ratio of three-membered rings to four-membered rings in silicon oxide contained in a dielectric film of the capacitor.

FIG. 6A is a schematic cross-sectional view for explanation of an example step of forming an insulating film.

FIG. 6B is a schematic cross-sectional view for explanation of an example step of forming a first electrode layer.

FIG. 6C is a schematic cross-sectional view for explanation of an example step of forming a dielectric film.

FIG. 6D is a schematic cross-sectional view for explanation of an example step of forming a second electrode layer.

FIG. 6E is a schematic cross-sectional view for explanation of an example step of forming a moisture-resistant film.

FIG. 6F is a schematic cross-sectional view for explanation of an example step of forming a protective layer.

FIG. 6G is a schematic cross-sectional view for explanation of an example step of forming a seed layer.

FIG. 6H is a schematic cross-sectional view for explanation of an example step of forming a first plating layer and a second plating layer.

FIG. 6I is a schematic cross-sectional view for explanation of an example step of removing part of the seed layer.

FIG. 6J is a schematic cross-sectional view for explanation of an example step of forming a photosensitive resin film.

FIG. 6K is a schematic cross-sectional view for explanation of an example step of forming a first resin member and a second resin member.

FIG. 7 is a cross-sectional view schematically illustrating an example of a capacitor according to a second embodiment of the present description.

FIG. 8 is a diagram illustrating an example of a matching circuit.

FIG. 9 is a diagram illustrating an example of a filtering circuit.

### DESCRIPTION OF THE PREFERRED EMBODIMENTS

Note that the configurations described herein are not intended to limit the present description and can be modified appropriately within the scope of the present description. In addition, a combination of individual preferred configurations herein is deemed to fall within the scope of the present description.

Note that embodiments described herein are examples and configurations described in different embodiments can be partially replaced or combined with one another. In embodiments to be described after the first embodiment, the description will focus on differences, and the description of the same elements as those of the first embodiment will be omitted. The same advantageous effects derived from the same configurations of different embodiments will not be repeated.

In the following description, the term “semiconductor device of the present description” is used where semiconductor devices of different embodiments are not differentiated from one another. The shape of the semiconductor device of the present description as well as the shapes and arrangements of the elements thereof are not limited to what are illustrated by way of example in the drawings.

In the following description, the semiconductor device of the present description will be described by taking a capacitor as an example of the semiconductor device. The semiconductor device of the present description can be a capacitor itself (i.e., a capacitor element) or can be a device including a capacitor.

### First Embodiment

A capacitor according to a first embodiment of the present description includes outer electrodes that are a first outer electrode coupled to a first electrode layer and a second outer electrode coupled to a second electrode layer.

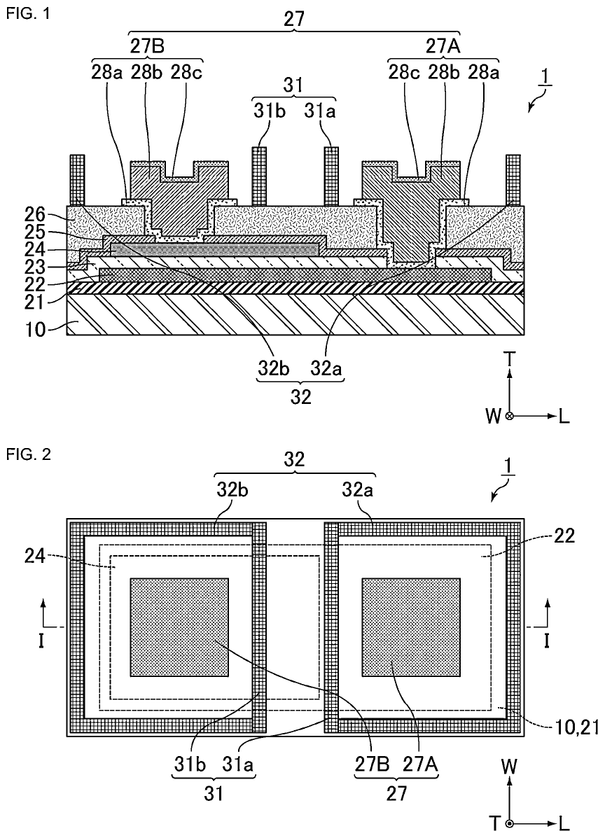

FIG. 1 is a cross-sectional view schematically illustrating an example of the capacitor according to the first embodiment of the present description. FIG. 2 is a plan view schematically illustrating the example of the capacitor according to the first embodiment of the present description. FIG. 1 illustrates the cross section of the capacitor taken along line I-I in FIG. 2.

In the present specification, the length direction, the width direction, and the thickness direction of the capacitor (semiconductor device) are defined as the directions of arrow L, arrow W, and arrow T, respectively, as indicated in FIGS. 1 and 2, etc. Here, the length direction L, the width direction W, and the thickness direction T orthogonally intersect each other.

As illustrated in FIGS. 1 and 2, a capacitor 1 includes a substrate 10, an insulating film 21 on the substrate 10, a first electrode layer 22 on the insulating film 21, a dielectric film 23 on the first electrode layer 22, a second electrode layer 24 on the dielectric film 23, a moisture-resistant film 25 on the dielectric film 23 and on the second electrode layer 24, a protective layer 26 on the moisture-resistant film 25, and outer electrodes 27 extending through the protective layer 26. The outer electrodes 27 include a first outer electrode 27A coupled to the first electrode layer 22 and a second outer electrode 27B coupled to the second electrode layer 24. The first outer electrode 27A pierces the protective layer 26, the moisture-resistant film 25, and the dielectric film 23. The second outer electrode 27B pierces the protective layer 26 and the moisture-resistant film 25.

The material of the substrate 10 is not specifically limited. The substrate 10 is preferably a semiconductor substrate, such as a silicon substrate or a gallium arsenide substrate, or an insulating substrate made of, for example, glass or alumina.

The insulating film 21 is disposed so as to cover one of the principal surfaces of the substrate 10 entirely. Although the insulating film 21 may be disposed so as to cover one principal surface of the substrate 10 entirely, it is necessary that the insulating film 21 be larger than the first electrode layer 22 and cover the entire region of the first electrode layer 22. Note that the insulating film 21 does not need to be provided if the substrate 10 is an insulating substrate made of glass, alumina, or the like.

The material of the insulating film 21 is not specifically limited but preferably, for example, is SiO₂, SiN, Al₂O₃, HfO₂, Ta₂O₅, or ZrO₂

The first electrode layer 22 is disposed so as to be spaced from the edges of the substrate 10. In other words, the edges of the first electrode layer 22 are positioned inside the edges of the substrate 10.

The material of the first electrode layer 22 is not specifically limited but preferably is, for example, Cu, Ag, Au, Al, Ni, Cr, Ti, or an alloy containing at least one of these.

The dielectric film 23 is disposed so as to cover the first electrode layer 22 except for an opening. The edges of the dielectric film 23 are positioned such that the dielectric film 23 covers the surface of the insulating film 21 in a region between the edges of the first electrode layer 22 and the edges of substrate 10, as illustrated in FIG. 1. The edges of the dielectric film 23, however, do not need to come to the edges of the substrate 10.

The dielectric film 23 is made of silicon oxide. More specifically, the silicon oxide of the dielectric film 23 contains three-membered ring structures and four-membered ring structures, and the ratio of the three-membered ring structures to the four-membered ring structures is 0.46 or less.

The thickness of the dielectric film 23 is not specifically limited but may be adjusted in accordance with a capacitance desired. For example, in the case of the capacitance being 3 pF or less, the thickness of the dielectric film 23 is preferably 0.2 μm or more, and more preferably 0.22 μm or more, while the thickness of the dielectric film 23 is preferably 5 μm or less, and more preferably 4 μm or less.

The second electrode layer 24 is disposed so as to oppose the first electrode layer 22 with the dielectric film 23 being interposed therebetween.

The material of the second electrode layer 24 is not specifically limited but preferably is, for example, Cu, Ag, Au, Al, Ni, Cr, Ti, or an alloy containing at least one of these.

The moisture-resistant film 25 is disposed so as to cover the dielectric film 23 and the second electrode layer 24 except for openings. Providing the moisture-resistant film 25 improves the moisture resistance of the capacitor element, more specifically, the moisture resistance of the dielectric film 23. Note that the moisture-resistant film 25 does not need to be provided.

The material of the moisture-resistant film 25 is not specifically limited but preferably is a moisture-resistant material, such as SiO₂ or SiN. The electric field is leaked to a region of the moisture-resistant film 25 or the protective layer 26 outside the region defined by the edges of the second electrode layer 24 that opposes the first electrode layer 22 with the dielectric film 23 interposed therebetween. SiO₂ has a dielectric constant of approximately a half of that of SiN. Accordingly, the use of SiO₂ as the material of the moisture-resistant film 25 can reduce the strength of the leaked electric field approximately by half compared with the case using SiN. The use of SiO, can reduce the likelihood of the electric field being leaked into the material that causes a large dielectric loss, such as the material of the protective layer 26 positioned outside the moisture-resistant film 25. As a result, the degradation of the Q-value of the capacitor 1 can be reduced.

The protective layer 26 has cavities formed at a position corresponding to the opening of the dielectric film 23 and the moisture-resistant film 25 (i.e., the opening superposing the first electrode layer 22) and also at a position corresponding to the opening of the moisture-resistant film 25 (i.e., the opening superposing the second electrode layer 24). The protective layer 26 protects the capacitor element, especially the dielectric film 23, from moisture.

The material of the protective layer 26 is not specifically limited but preferably is a resin, such as polyimide or a resin contained in solder resist.

The material of the outer electrodes 27 is not specifically limited but preferably is Cu, Ni, Ag, Au, or Al, for example. The outer electrodes 27 may have a single-layer structure or may have a multi-layer structure. The outermost surface of each outer electrode 27 is preferably made of Au or Sn.

When the first outer electrode 27A has the multi-layer structure, the first outer electrode 27A may include a seed layer 28a, a first plating layer 28b, and a second plating layer 28c in the order from the substrate 10 as illustrated in FIG. 1.

For example, the seed layer 28a of the first outer electrode 27A is made of a multilayer body (Ti/Cu) having a conductive layer of titanium (Ti) and a conductive layer of copper (Cu).

For example, the first plating layer 28b of the first outer electrode 27A is made of nickel (Ni).

For example, the second plating layer 28c of the first outer electrode 27A is made of gold (Au) or tin (Sn).

When the second outer electrode 27B has a multi-layer structure, the second outer electrode 27B may include the seed layer 28a, the first plating layer 28b, and the second plating layer 28c in the order from the substrate 10 as illustrated in FIG. 1.

For example, the seed layer 28a of the second outer electrode 27B is made of the multilayer body (Ti/Cu) having the conductive layer of titanium (Ti) and the conductive layer of copper (Cu).

For example, the first plating layer 28b of the second outer electrode 27B is made of nickel (Ni).

For example, the second plating layer 28c of the second outer electrode 27B is made of gold (Au) or tin (Sn).

The materials of the first outer electrode 27A and the second outer electrode 27B may be the same or may be different.

As illustrated in FIGS. 1 and 2, a first resin member 31 may be formed between the first outer electrode 27A and the second outer electrode 27B as viewed in plan in the thickness direction T. For example, the first resin member 31 is formed on the surface of the protective layer 26.

As illustrated in FIG. 1, in the thickness direction T, the distal end of the first resin member 31 preferably comes to a position higher than the distal ends of the first outer electrode 27A and the second outer electrode 27B. With this configuration, when the capacitor 1 is mounted on a circuit board, the first resin member 31 is brought into contact with the circuit board (for example, with the upper surface, a land, or a solder bump of the circuit board) before the first outer electrode 27A and the second outer electrode 27B come into contact. As a result, the first resin member 31 receives load and thereby reduces the load applied to the first outer electrode 27A and to the second outer electrode 27B. This reduces the load transferred to the capacitor element via the first outer electrode 27A and the second outer electrode 27B and thereby reduces the breakage of the capacitor element and, especially, the dielectric film 23.

The first resin member 31 preferably contains at least one resin selected from the group consisting of the resin contained in the solder resist, polyimide resin, polyimide-amide resin, and epoxy resin. The first resin member 31 is preferably a hardened product of photosensitive resin.

The first resin member 31 may include a first wall portion 31a formed near the first outer electrode 27A and a second wall portion 31b formed near the second outer electrode 27B and spaced from the first wall portion 31a. As illustrated in FIG. 2, the first wall portion 31a and the second wall portion 31b are disposed parallel to each other as viewed in plan.

The first wall portion 31a may have a hole being in communication with the space between the first wall portion 31a and the second wall portion 31b. Similarly, the second wall portion 31b may have a hole being in communication with the space between the first wall portion 31a and the second wall portion 31b.

As illustrated in FIGS. 1 and 2, a second resin member 32 is formed at a position between the first outer electrode 27A and edges of the substrate 10 and also at a position between the second outer electrode 27B and edges of the substrate 10 as viewed in plan in the thickness direction T. For example, the second resin member 32 is formed on the surface of the protective layer 26. Alternatively, the second resin member 32 may be formed on the substrate 10 at positions outside the protective layer 26.

As illustrated in FIG. 1, in the thickness direction T, the distal end of the second resin member 32 preferably comes to a position higher than the distal ends of the first outer electrode 27A and the second outer electrode 27B. With this configuration, when the capacitor 1 is mounted, for example, on a circuit board, the load can be distributed widely over the second resin member 32, which sufficiently reduces the load applied to the capacitor element, especially to the dielectric film 23.

In addition, the distal end of the second resin member 32 is preferably positioned lower than the distal end of the first resin member 31 in the thickness direction T as illustrated in FIG. 1. With this configuration, when the capacitor 1 is mounted on the circuit board, the capacitor 1 is held by the first resin member 31 stably on the circuit board.

The second resin member 32 preferably contains at least one resin selected from the group consisting of the resin contained in the solder resist, polyimide resin, polyimide-amide resin, and epoxy resin. The second resin member 32 is preferably a hardened product of photosensitive resin.

The resins contained in the first resin member 31 and in the second resin member 32 may be the same or may be different from each other.

As illustrated in FIG. 2, the second resin member 32 preferably include a first peripheral portion 32a and a second peripheral portion 32b. As viewed in plan in the thickness direction T, the first peripheral portion 32a is formed along edges of the substrate 10 at positions between the first outer electrode 27A and the edges of the substrate 10, and the second peripheral portion 32b is formed along edges of the substrate 10 at positions between the second outer electrode 27B and the edges of the substrate 10.

The first wall portion 31a and the first peripheral portion 32a are preferably joined to each other. The second wall portion 31b and the second peripheral portion 32b are preferably joined to each other.

In the semiconductor device of the present description, the dielectric film is made of silicon oxide. The silicon oxide contained in the dielectric film includes three-membered ring structures and the four-membered ring structures, and the ratio of the three-membered ring structures to the four-membered ring structures (otherwise referred to as the “ratio of three-membered rings to four-membered rings”) is 0.46 or less.

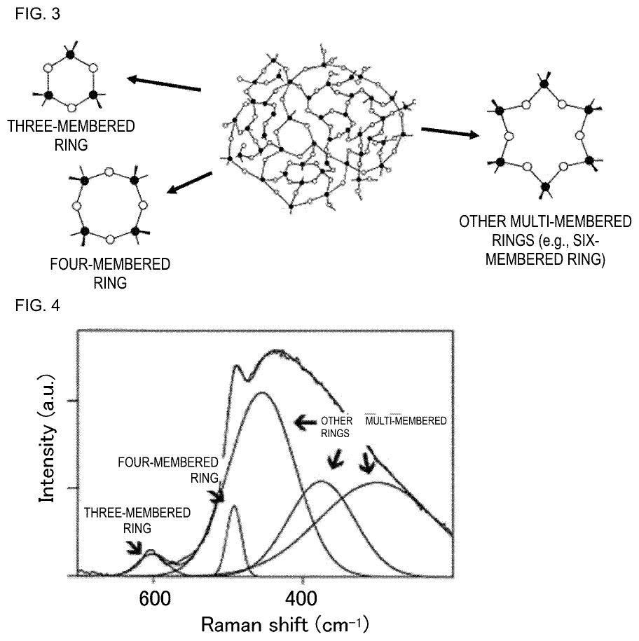

FIG. 3 schematically illustrates an example structure of silicon oxide.

The silicon oxide contained in the dielectric film has an amorphous structure. The amorphous structure is a disordered structure having no periodicity. As illustrated in FIG. 3, the silicon oxide contains ring-like structures without periodicity in a large region. In a small region, however, the silicon oxide contains a mixture of periodic ring-like structures, such as three-membered rings, four-membered rings, and other multi-membered rings.

FIG. 4 is an example of Raman spectrum of the silicon oxide.

As illustrated in FIG. 4, the ratio of multi-membered ring structures in the silicon oxide contained in the dielectric film can be obtained by observing the Raman spectrum and separating peaks of waves corresponding to respective multi-membered ring structures.

More specifically, the silicon oxide is analyzed using a Raman microscope (using a laser beam having a wavelength of 532 nm), and peaks can be observed in the vicinity of 490 cm⁻¹ and of 608 cm⁻¹. These peaks correspond to the four-membered ring structures and the three-membered ring structures, respectively, and the ratio of three-membered rings to four-membered rings can be obtained from the ratio of peak intensities for these structures.

In the high-frequency band between 1 to 10 GHZ, the dielectric loss of the dielectric film increases as the ratio of the three-membered ring structures in the silicon oxide contained in the dielectric film increases. On the other hand, the dielectric loss of the dielectric film decreases as the ratio of the four-membered ring structures increases.

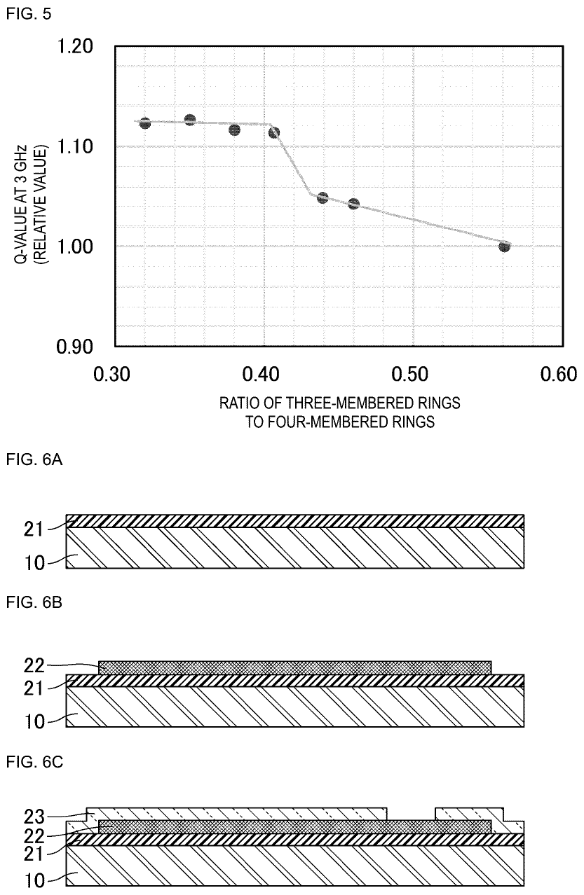

FIG. 5 is a graph illustrating a relationship between the Q-value of a 0.2 pF capacitor and the ratio of three-membered rings to four-membered rings in the silicon oxide contained in the dielectric film of the capacitor.

When a dielectric film was deposited at room temperature using a confronting-target-type RF sputtering system with an SiO₂ target, the ratio of three-membered rings to four-membered rings in the deposited dielectric film was 0.56. FIG. 5 plots relative Q-values normalized with the Q-value of this dielectric film being set to be 1.

As can be seen from FIG. 5, the Q-value improves when the ratio of three-membered rings to four-membered rings in the silicon oxide contained in the dielectric film is 0.46 or less, and the Q-value improves significantly when the ratio is less than 0.44. In addition, when the ratio of three-membered rings to four-membered rings in the silicon oxide contained in the dielectric film is 0.41 or less, the Q-value increases almost to the maximum.

Accordingly, the ratio of the three-membered ring structures to the four-membered ring structures in the silicon oxide contained in the dielectric film is preferably less than 0.44, and more preferably 0.41 or less.

The lower limit of the ratio of the three-membered ring structures to the four-membered ring structures in the silicon oxide contained in the dielectric film is not specifically limited but may be, for example, 0.30 or more.

In the case where the semiconductor device of the present description includes the moisture-resistant film, it is preferable that the moisture-resistant film be made of silicon oxide and the ratio of the three-membered ring structures to the four-membered ring structures in the silicon oxide contained in the moisture-resistant film be 0.46 or less.

The decrease of the Q-value due to the leakage of the electric field into the moisture-resistant film, etc., can be further reduced when the moisture-resistant film is made of the same silicon oxide as that of the dielectric film having a small dielectric loss.

The ratio of the three-membered ring structures to the four-membered ring structures in the silicon oxide contained in the moisture-resistant film is preferably less than 0.44 and more preferably is 0.41 or less.

The lower limit of the ratio of the three-membered ring structures to the four-membered ring structures in the silicon oxide contained in the moisture-resistant film is not specifically limited but may be, for example, 0.30 or more.

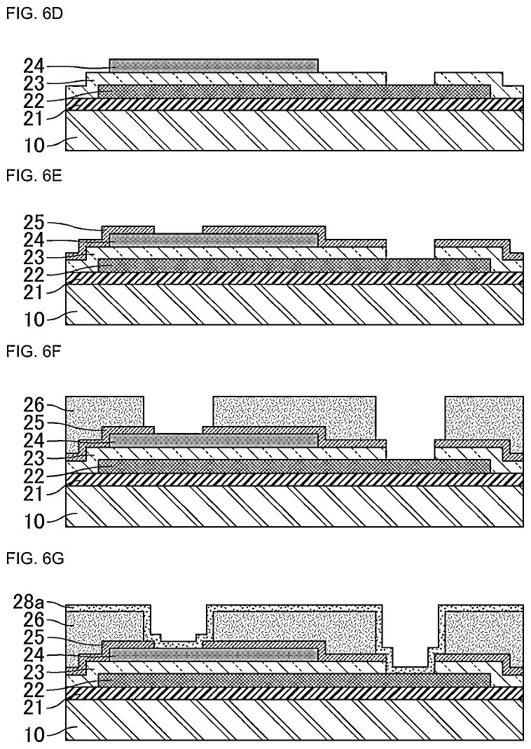

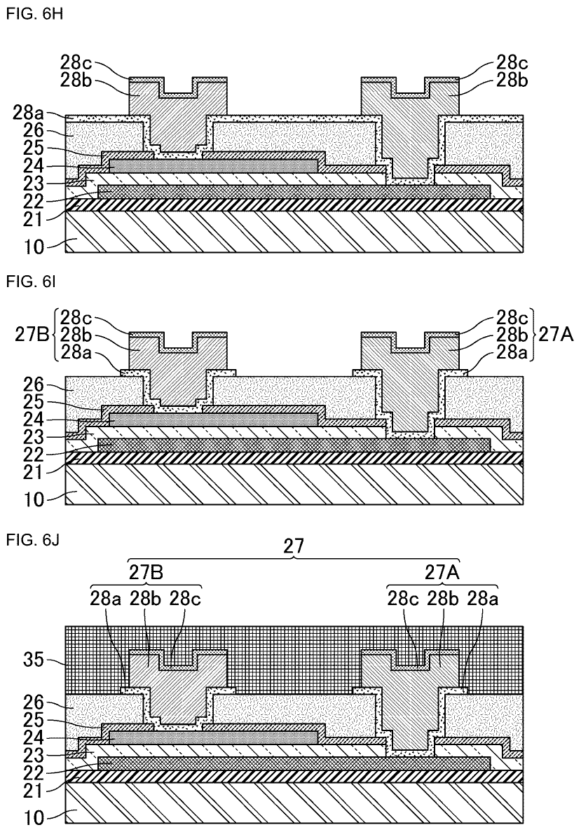

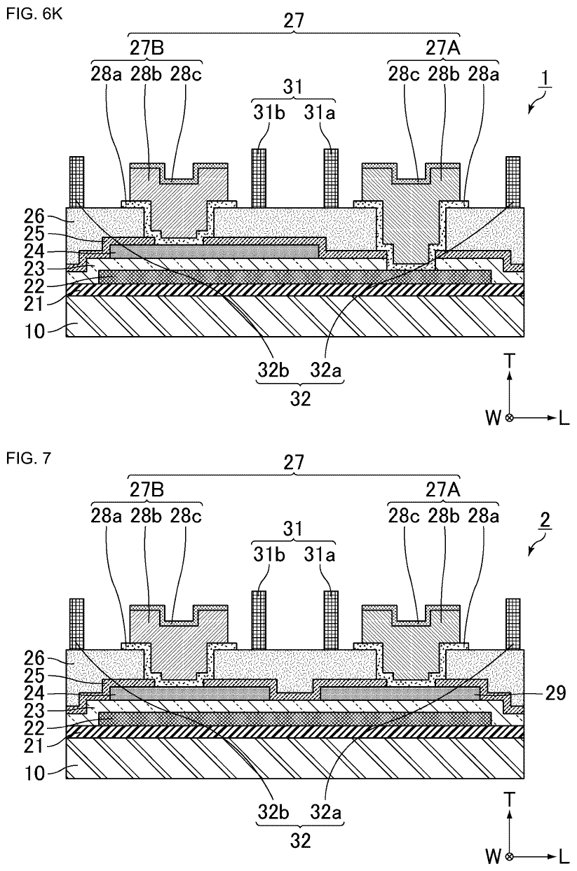

The capacitor 1 of FIG. 1 is manufactured, for example, through the following steps. FIGS. 6A to 6K are cross-sectional views schematically illustrating an example method of manufacturing the capacitor according to the first embodiment of the present description.

### <Formation of Insulating Film>

FIG. 6A is a schematic cross-sectional view for explanation of an example step of forming an insulating film.

As illustrated in FIG. 6A, the insulating film 21 is formed on the substrate 10 using, for example, thermal oxidation, sputtering, or chemical vapor deposition.

### <Formation of First Electrode Layer>

FIG. 6B is a schematic cross-sectional view for explanation of an example step of forming a first electrode layer.

A conductive layer made of the material of the first electrode layer 22 is formed, for example, by sputtering on the surface of the insulating film 21, the surface facing opposite to the substrate 10. The conductive layer is subsequently patterned using photolithography and etching combinedly, thereby forming the first electrode layer 22 as illustrated in FIG. 6B. More specifically, the first electrode layer 22 is formed so as to be spaced from the edges of the substrate 10.

### <Formation of Dielectric Film>

FIG. 6C is a schematic cross-sectional view for explanation of an example step of forming a dielectric film.

A layer made of the material of the dielectric film 23 is formed using, for example, sputtering or chemical vapor deposition so as to cover the first electrode layer 22. It is effective to reduce the partial pressure of hydrogen in a gas used for film deposition in order to decrease the ratio of three-membered rings to four-membered rings in the silicon oxide contained in the dielectric film 23. The chemical vapor deposition uses a gas containing hydrogen. Accordingly, it is effective to use sputtering because the sputtering does not use the gas containing hydrogen and the silicon oxide formed by sputtering has a lower content of hydrogen. For both sputtering and chemical vapor deposition, the amount of water captured in the deposited film can be reduced by lowering the pressure in the deposition chamber as much as possible before the film deposition starts (i.e., immediately before the gas is introduced) or by suppressing degassing of the system caused by temperature increase during film deposition. Degassing the deposited film may be performed, when necessary, by heating the film to a temperature of 300° C. or more and 650° C. or less. The layer is subsequently patterned, for example, using photolithography and etching combinedly to form the dielectric film 23 as illustrated in FIG. 6C. More specifically, the dielectric film 23 is formed so as to have an opening in which part of the first electrode layer 22 is exposed.

### <Formation of Second Electrode Layer>

FIG. 6D is a schematic cross-sectional view for explanation of an example step of forming a second electrode layer.

A conductive layer made of the material of the second electrode layer 24 is formed, for example, by sputtering on a surface of the structure illustrated in FIG. 6C, the surface being opposite to the substrate 10. The conductive layer is subsequently patterned, for example, using photolithography and etching combinedly to form the second electrode layer 24 as illustrated in FIG. 6D. More specifically, the second electrode layer 24 is formed so as to oppose the first electrode layer 22 with the dielectric film 23 being interposed therebetween.

### <Formation of Moisture-Resistant Film>

FIG. 6E is a schematic cross-sectional view for explanation of an example step of forming a moisture-resistant film.

A layer made of the material of the moisture-resistant film 25 is formed, for example, by chemical vapor deposition on a surface of the structure illustrated in FIG. 6D, the surface being opposite to the substrate 10. The sputtering may be used to form the moisture-resistant film 25 in order to reduce the ratio of three-membered rings to four-membered rings in the silicon oxide, as is the case for the dielectric film 23. The layer is subsequently patterned, for example, using photolithography and etching combinedly to form the moisture-resistant film 25 as illustrated in FIG. 6E. More specifically, the moisture-resistant film 25 is formed so as to have an opening in which part of the first electrode layer 22 is exposed at a position corresponding to the opening of the dielectric film 23 and so as to have another opening in which part of the second electrode layer 24 is exposed.

### <Formation of Protective Layer>

FIG. 6F is a schematic cross-sectional view for explanation of an example step of forming a protective layer.

A layer made of the material of the protective layer 26 is formed, for example, by spin coating on a surface of the structure illustrated in FIG. 6E, the surface being opposite to the substrate 10. In order to form the protective layer 26 as illustrated in FIG. 6F, the layer is subsequently patterned, for example, using photolithography if the protective layer 26 is made of a photosensitive material or using photolithography and etching combinedly if the protective layer 26 is made of a non-photosensitive material. More specifically, the protective layer 26 is formed so as to have a cavity in which the part of the first electrode layer 22 is exposed at a position corresponding to the openings of the dielectric film 23 and the moisture-resistant film 25 and formed so as to have another cavity in which the part of the second electrode layer 24 is exposed at a position corresponding to the opening of the moisture-resistant film 25.

### <Formation of Outer Electrodes>

FIG. 6G is a schematic cross-sectional view for explanation of an example step of forming a seed layer. FIG. 6H is a schematic cross-sectional view for explanation of an example step of forming a first plating layer and a second plating layer. FIG. 6I is a schematic cross-sectional view for explanation of an example step of removing part of the seed layer.

As illustrated in FIG. 6G, the seed layer 28a is formed on a surface of the structure illustrated in FIG. 6F, the surface being opposite to the substrate 10. As illustrated in FIG. 6H, the first plating layer 28b and subsequently the second plating layer 28c are formed using plating and photolithography combinedly. Subsequently, as illustrated in FIG. 6I, part of the seed layer 28a is removed, for example, by etching. Thus, the outer electrodes 27 including the first outer electrode 27A and the second outer electrode 27B are formed as illustrated in FIG. 6I. More specifically, the first outer electrode 27A is formed so as to be coupled to the first electrode layer 22 through the openings of the dielectric film 23 and the moisture-resistant film 25 and through the cavity of the protective layer 26. In addition, the second outer electrode 27B is formed so as to be coupled to the second electrode layer 24 through the opening of the moisture-resistant film 25 and through the cavity of the protective layer 26.

### <Formation of First Resin Member and Second Resin Member>

FIG. 6J is a schematic cross-sectional view for explanation of an example step of forming a photosensitive resin film. FIG. 6K is a schematic cross-sectional view for explanation of an example step of forming a first resin member and a second resin member.

As illustrated in FIG. 6J, a photosensitive resin film 35 is formed so as to cover the protective layer 26 and the outer electrodes 27. The photosensitive resin film 35 is patterned using photolithography to form the first resin member 31 and the second resin member 32 as illustrated in FIG. 6K.

Thus, the capacitor 1 illustrated in FIG. 1 is manufactured.

A method of manufacturing a single capacitor element has been described above. However, multiple capacitor elements may be manufactured simultaneously by forming multiple capacitor elements on a single substrate 10 and by cutting the substrate 10 using a dicing machine to produce individual capacitor elements.

### Second Embodiment

A capacitor according to a second embodiment of the present description further includes a third electrode layer formed on the dielectric film at a position spaced from the second electrode layer. The outer electrodes includes the first outer electrode coupled to the third electrode layer and the second outer electrode coupled to the second electrode layer.

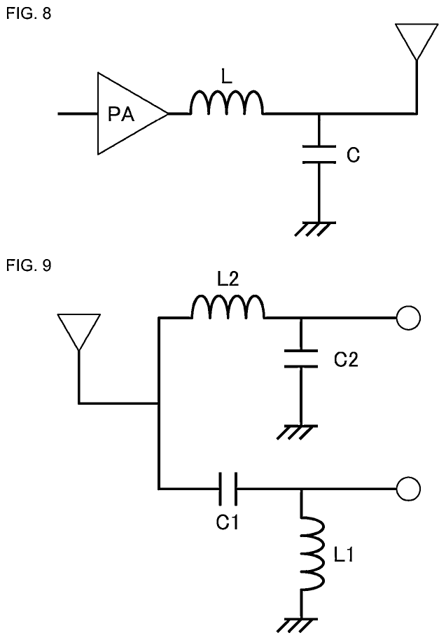

FIG. 7 is a cross-sectional view schematically illustrating an example of the capacitor according to the second embodiment of the present description.

A capacitor 2 illustrated in FIG. 7 includes the substrate 10, the insulating film 21 on the substrate 10, the first electrode layer 22 on the insulating film 21, the dielectric film 23 on the first electrode layer 22, and the second electrode layer 24 on the dielectric film 23. The capacitor 2 also includes the third electrode layer 29, the moisture-resistant film 25, the protective layer 26, and the outer electrodes 27. The third electrode layer 29 is on the dielectric film 23 at a position spaced from the second electrode layer 24. The moisture-resistant film 25 is on the dielectric film 23, on the second electrode layer 24, and on the third electrode layer 29. The protective layer 26 is on the moisture-resistant film 25, and the outer electrodes 27 are extend through the protective layer 26. The outer electrodes 27 include the first outer electrode 27A coupled to the third electrode layer 29 and the second outer electrode 27B coupled to the second electrode layer 24. The first outer electrode 27A pierces the protective layer 26 and the moisture-resistant film 25. The second outer electrode 27B also pierces the protective layer 26 and the moisture-resistant film 25.

As illustrated in FIG. 1, a capacitor is formed in a right region of the capacitor 1. In the capacitor 2 illustrated in FIG. 7, however, capacitors are formed in right and left regions, respectively. In the capacitor 1 of FIG. 1, the first outer electrode 27A is connected to the first electrode layer 22. In the capacitor 2 of FIG. 7, this connection portion is replaced with a structure in which the first electrode layer 22, the dielectric film 23, and the third electrode layer 29 are stacked in this order. Accordingly, the structure illustrated in FIG. 7 does not require an additional element-forming space when the structure of FIG. 7 is compared to the structure of FIG. 1. As a result, a capacitor having a low capacitance can be manufactured without increasing the element-forming space. This structure is especially useful where there is a limitation to increase the thickness of the dielectric film.

### Other Embodiments

The semiconductor device of the present description is not limited to the above embodiments but is subject to modification and alteration within the scope of the present description in terms of, for example, the structure and manufacturing conditions of the semiconductor device, such as the capacitor.

The semiconductor device of the present description has high-Q characteristics and accordingly is used as a capacitor suitably in a matching circuit and in a filtering circuit. The matching circuit and the filtering circuit that use the semiconductor device of the present description fall within the scope of the present description.

FIG. 8 is a diagram illustrating an example of a matching circuit.

For example, when the semiconductor device of the present description is used as a capacitor C of the matching circuit of FIG. 8, the overall power consumption of the circuit can be reduced. For example, the overall power consumption of the circuit is assumed to be 100% when the ratio of the three-membered ring structures to the four-membered ring structures in the silicon oxide contained in the dielectric film is 0.56. When the ratio of the three-membered ring structures to the four-membered ring structures in the silicon oxide contained in the dielectric film is 0.41, the power consumption of the circuit decreases to 91%.

FIG. 9 is a diagram illustrating an example of a filtering circuit.

For example, when the semiconductor device of the present description is used as a capacitor C1 of the filtering circuit of FIG. 9, the overall power consumption of the circuit can be reduced. For example, the overall power consumption of the circuit is assumed to be 100% when the ratio of the three-membered ring structures to the four-membered ring structures in the silicon oxide contained in the dielectric film is 0.56. When the ratio of the three-membered ring structures to the four-membered ring structures in the silicon oxide contained in the dielectric film is 0.41, the power consumption of the circuit decreases to 96%.

### REFERENCE SIGNS LIST

1, 2 capacitor (semiconductor device)
10 substrate
21 insulating film
22 first electrode layer
23 dielectric film
24 second electrode layer
25 moisture-resistant film
26 protective layer
27 outer electrode
27A first outer electrode
27B second outer electrode
28a seed layer
28b first plating layer
28c second plating layer
29 third electrode layer
31 first resin member
31a first wall portion
31b second wall portion
32 second resin member
32a first peripheral portion
32b second peripheral portion
35 photosensitive resin film

1. A semiconductor device comprising:
a substrate;
a first electrode layer on the substrate;
a dielectric film on the first electrode layer, the dielectric film containing silicon oxide, and a ratio of three-membered ring structures to four-membered ring structures in the silicon oxide is 0.46 or less;
a second electrode layer on the dielectric film;
a protective layer covering the first electrode layer and the second electrode layer; and
outer electrodes piercing the protective layer.

2. The semiconductor device according to claim 1, wherein the ratio of the three-membered ring structures to the four-membered ring structures in the silicon oxide contained in the dielectric film is less than 0.44.

3. The semiconductor device according to claim 1, wherein the ratio of the three-membered ring structures to the four-membered ring structures in the silicon oxide contained in the dielectric film is 0.41 or less.

4. The semiconductor device according to claim 1, further comprising:
a moisture-resistant film on the dielectric film and on the second electrode layer, wherein
the protective layer is on the moisture-resistant film.

5. The semiconductor device according to claim 4, wherein
the moisture-resistant film is made of silicon oxide, and
a ratio of three-membered ring structures to four-membered ring structures in the silicon oxide contained in the moisture-resistant film is 0.46 or less.

6. The semiconductor device according to claim 5, wherein the ratio of the three-membered ring structures to the four-membered ring structures in the silicon oxide contained in the moisture-resistant film is less than 0.44.

7. The semiconductor device according to claim 5, wherein the ratio of the three-membered ring structures to the four-membered ring structures in the silicon oxide contained in the moisture-resistant film is 0.41 or less.

8. The semiconductor device according to claim 1, wherein the outer electrodes include a first outer electrode coupled to the first electrode layer and a second outer electrode coupled to the second electrode layer.

9. The semiconductor device according to claim 8, further comprising a first resin member between the first outer electrode and the second outer electrode as viewed in a plan in a thickness direction of the semiconductor device.

10. The semiconductor device according to claim 9, wherein, in the thickness direction, a distal end of the first resin member is at a position higher than distal ends of the first outer electrode and the second outer electrode.

11. The semiconductor device according to claim 9, further comprising a second resin member between the first outer electrode and edges of the substrate and between the second outer electrode and edges of the substrate as viewed in the plan view in the thickness direction of the semiconductor device.

12. The semiconductor device according to claim 11, wherein, in the thickness direction, a distal end of the first resin member is at a position higher than distal ends of the first outer electrode and the second outer electrode and/or a distal end of the second resin member is at a position higher than the distal ends of the first outer electrode and the second outer electrode.

13. The semiconductor device according to claim 1, further comprising:
a third electrode layer on the dielectric film at a position spaced from the second electrode layer, wherein
the outer electrodes include a first outer electrode coupled to the third electrode layer and a second outer electrode coupled to the second electrode layer.

14. The semiconductor device according to claim 13, further comprising:
a moisture-resistant film on the dielectric film and on the second electrode layer, wherein
the protective layer is on the moisture-resistant film.

15. The semiconductor device according to claim 14, wherein
the moisture-resistant film is made of silicon oxide, and
a ratio of three-membered ring structures to four-membered ring structures in the silicon oxide contained in the moisture-resistant film is 0.46 or less.

16. The semiconductor device according to claim 15, wherein the ratio of the three-membered ring structures to the four-membered ring structures in the silicon oxide contained in the moisture-resistant film is less than 0.44.

17. The semiconductor device according to claim 15, wherein the ratio of the three-membered ring structures to the four-membered ring structures in the silicon oxide contained in the moisture-resistant film is 0.41 or less.

18. A matching circuit comprising the semiconductor device according to claim 1.

19. A filtering circuit comprising the semiconductor device according to claim 1.
